(19) United States
(12) Patent Application Publication
(10) Pub. No.: US 2017/0079140 A1
(43) Pub. Date: Mar. 16, 2017

(54) SYSTEM, APPARATUS AND METHOD FOR INTERCONNECTING CIRCUIT BOARDS

(71) Applicant: Intel Corporation, Santa Clara, CA (US)

(72) Inventors: Raul Enriquez Shibayama, Zapopan (MX); Kai Xiao, University Place, WA (US); Nicte A. Zavala Castro, Guadalajara (MX); Beom-Taek Lee, Mountain View, CA (US)

(21) Appl. No.: 14/851,083

(22) Filed: Sep. 11, 2015

(51) Int. Cl. H05K 1/14; H05K 1/11; H05K 1/02; H05K 1/18

(52) U.S. Cl. CPC H05K 1/144; H05K 1/181; H05K 1/115; H05K 1/0298; H05K 2201/10159; H05K 2201/10734; H05K 2201/09545

(57) ABSTRACT

In one embodiment, first and second circuit boards may be coupled together. The first circuit board may include a first trace to electrically couple a first integrated circuit to a first via of the first circuit board. In turn, the second circuit board may include a second trace to electrically couple a first contact of a first memory socket adapted to the first circuit board and a first contact of a second memory socket adapted to the first circuit board. This second trace, when the circuit boards are coupled together, is to electrically couple to a first via of the second circuit board, to enable the first via of the second board to electrically couple to the first via of the first circuit board. Other embodiments are described and claimed.

### BACKGROUND

Circuit boards are used to provide interconnection between a variety of different components within a given computer system. Oftentimes these circuit boards are designed with many internal layers that provide for routing of interconnection lines between the different components adapted to the circuit board as well as other components of a system. Reducing the number of metal layers in a circuit board can reduce system cost. However, by reducing the number of layers, challenges for high-speed signaling can be presented. For example, with a reduced numbers of layers, rather than using a T-topology for interconnection of multiple memory devices to one or more components, a daisy chain interconnection is used. However, a daisy chain interconnection can negatively impact performance, such as communication signaling speeds.

### BRIEF DESCRIPTION OF THE DRAWINGS

FIG. 1 is a block diagram of a connection architecture in accordance with an embodiment of the present invention.

FIG. 2 is a block diagram of a connection architecture in accordance with another embodiment.

FIG. 3 is an alternate implementation of a connection architecture in accordance with an embodiment.

FIG. 4 is a block diagram of another connection arrangement in accordance with an embodiment of the present invention.

FIG. 5 is a flow diagram of a method for forming a multi-circuit board arrangement in accordance with an embodiment of the present invention.

FIG. 6 is a block diagram of a multi-domain processor in accordance with an embodiment of the present invention.

FIG. 7 is a block diagram of a representative computer system.

### DETAILED DESCRIPTION

Referring now to FIG. 1, shown is a block diagram of a connection architecture in accordance with an embodiment of the present invention. Architecture 100 is illustrated in cross-section of a circuit board arrangement, including a primary or main printed circuit board (PCB) 110 and a secondary or bridge circuit board 120. By providing a bridge circuit board as described herein, embodiments enable a connector-less attachment of memory-containing boards (sockets) to enable a T-topology for memory module interconnection (referred to herein as a “connector-less T-topology”).

More specifically as shown in FIG. 1, a T-topology is realized by interconnection of circuitry on two different circuit boards. As seen, main circuit board 110 includes a first trace 112, which may be a given electrical trace (of a given conductive material) formed on a single layer of the circuit board, which is coupled to a via 114. Circuit board 110 may be a multi-layer circuit board such as a motherboard of a desktop computer, server computer, communication system, networking system, storage system, or other computing device. Although the scope of the present invention is not limited in this regard, the amount of layers of circuit board 110 can vary, and example implementations may include between 12 and 16 layers. Note that by leveraging the connector-less T-topology described herein, fewer layers may be present in a given circuit board, reducing board cost, size and so forth. That is, with the arrangement shown in FIG. 1, additional connectors, such as on-board or above-board direct connection (e.g., a physical connector), to interconnect multiple memory sockets can be avoided.

To form the T-topology, trace 112 couples to via 114 formed within circuit board 110. In an embodiment, via 114 may be implemented as a plated through hole (PTH) via to enable electrical connection with trace 112. As further illustrated, via 114 also electrically connects with a corresponding via 124 present within bridge circuit board 120.

Still with reference to FIG. 1, main circuit board 110 further includes a plurality of non-conductive vias 115a and 115b (which may be non-plated through hole mounted (THM) vias). In other embodiments, vias 115a and 115b may be plated or conductive vias. As shown, these vias are configured to receive corresponding contacts of memory module sockets 140a and 140b. Although only two memory sockets are shown in FIG. 1, understand that additional sockets may be present in other embodiments. Sockets 140 provide interconnection between memory devices such as dual in-line memory modules (DIMMs) coupled into sockets 140 and corresponding traces within circuit board 110 that in turn may couple to one or more semiconductor devices such as integrated circuits (not shown in FIG. 1) coupled to the circuit board.

In the illustration of FIG. 1, sockets 140a and 140b include corresponding pins or contacts 142a and 142b. As seen, these contacts extend through the height of main circuit board 110 and are adapted through corresponding vias within bridge circuit board 120. As illustrated, contact 142a is adapted through via 115a of main circuit board 110 and electrically couples to via 125a of bridge circuit board 120. In an embodiment, via 125a may be a conductive or plated through hole mounted (THM) via such that electrical connection is provided between contact 142a and via 125a. In turn, via 125a couples electrically to trace 122 within bridge circuit board 120 that in turn is coupled to a via 124 of bridge circuit board 120, which also may be a PTH via. Similarly, contact 142b is adapted through via 115b of main circuit board 110 and electrically couples to via 125b of bridge circuit board 120. Wave soldering points (e.g. solder dots 152 and 154) ensure an electrical path from plated THM vias 125a and 125b to contacts 142a and 142b, and thus to the DIMM devices themselves. Via 125b also couples electrically to trace 122, in turn coupled to via 124.

In this way, electrical connection between contacts 142a and 142b of sockets 140a and 140b and trace 112 of main circuit board 110 is effected, by a path including trace 122, via 124, electrical contact 132 (which in an embodiment may be a solder bump) and via 114. As such, a connector-less T-topology is realized using bridge circuit board 120 with its trace 122 electrically coupling vias 125a and 125b (in turn electrically coupled to memory devices within sockets 140a and 140b). Note while this connection is shown for a single common pin of multiple sockets to all couple to one pad of a device (such as an integrated circuit adapted on main circuit board 110), understand that there may be the same number of connections as pins in the memory sockets, at least for bit and clock signals.

In the arrangement of FIG. 1, bridge circuit board 120 enables inclusion of additional layers within a DIMM connector region (generally region 145) of main circuit board 110, enabling a T-topology implementation while maintaining low layer count in main circuit board 110. Also understand that bridge circuit board 120 can be configured to be of a smaller height (and width) than main circuit board 110, as it is only used to provide interconnections within this DIMM connector region 145.

Small PTH vias, such as via 114 are used to connect signals (e.g., so-called double data rate (DDR) signals) from and to memory devices using main circuit board 120 and bridge circuit board 110. Note that THM vias such as non-plated vias 115a and 115b are provided to enable adaptation of contacts of DIMM sockets through main circuit board 120, while corresponding THM vias (such as vias 125a and 125b) within bridge circuit 120 are plated to enable electrical connection.

Note that solder bump 132, along with bumps 130 and 134, may be formed during a manufacturing process such as a reflow solder operation in which the two boards are coupled together. Understand that solder bumps 130 and 134 may not be for electrical connection, but instead to provide mechanical stability. In some cases however, the bumps may couple to a ground potential for use as ground pads. Solder dots 152 and 154 may be adapted to contacts 142a and 142b during a wave solder operation. Understand while shown at this high level in the illustration of FIG. 1, many variations and alternatives are possible.

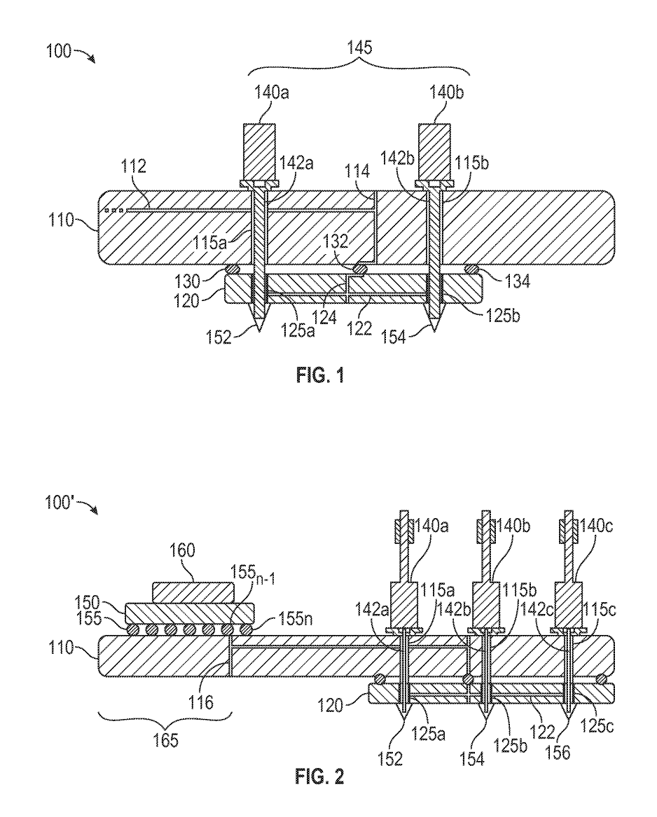

Referring now to FIG. 2, shown is a block diagram of a connection architecture in accordance with another embodiment. In the embodiment of FIG. 2, architecture 100′ may be configured similarly to architecture 100 of FIG. 1. However, in this embodiment, a 3-DIMM topology is provided in which an additional memory socket 140c is provided, which is interconnected to the same trace 122 within bridge circuit board 120 by way of via 115c of main circuit board 110 and electrical interconnection of contact 142c with via 125c within bridge circuit board 120 by solder dot 156.

FIG. 2 further shows interconnection of trace 112 to an integrated circuit (IC) 160 including at least one semiconductor die, such as a processor or other system on-chip (SoC) including an integrated memory controller. As shown, IC 160 is coupled into a socket or package 150 that interconnects onto main circuit board 110, e.g., via a surface mount technology (SMT) interconnection, such as by way of a plurality of solder bumps 155₀-155ₙ. As examples, an IC package circuit (including one or more die), can be connected through SMT technology, or a socket (including one or more die in a package) can be connected through SMT technology.

Thus as illustrated in FIG. 2, connection between memory devices within sockets 140a-140c and IC 160 is realized, by way of a via 116, which couples in turn to a solder bump 155ₙ₋₁ of a plurality of solder bumps 155₀-155ₙ that interconnect integrated circuit 160 with various traces on main circuit board 110. Although not shown in FIG. 2, understand that a thermal solution may be adapted above integrated circuit 160.

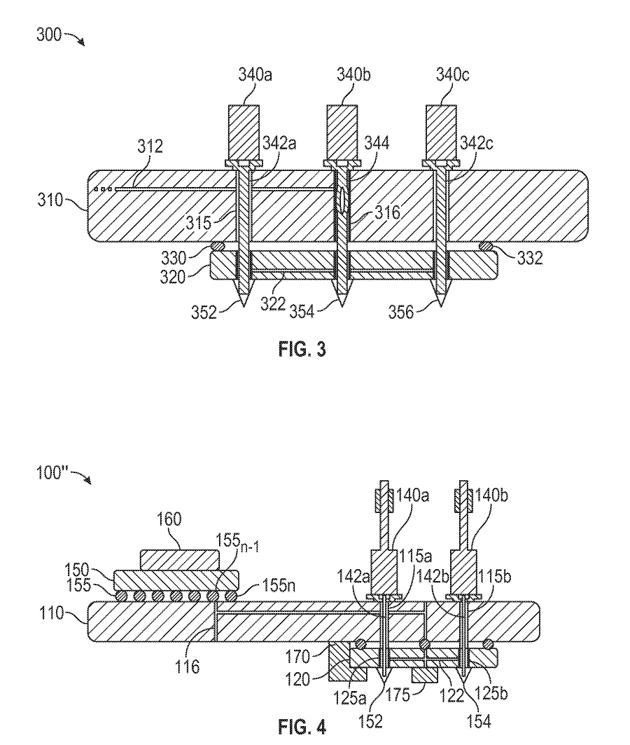

In other embodiments, a press-fit through (PFT) contact can be used to interconnect multiple memory devices without the need for a PTH via interconnecting main circuit board and bridge circuit board. Referring now to FIG. 3, shown is an alternate implementation of a connection architecture 300 in accordance with an embodiment. As shown in FIG. 3, connector 340b includes a contact 344 having a PFT arrangement with a longtail that is adapted within a plated PFT via 316. In this arrangement, memory modules coupled to sockets 340a-340c interconnect via trace 322 and, by way of contact 344, to trace 312, that in turn may couple to a given one or more integrated circuits (such as a processor or SoC, as described above). By way of this connection, the need for an internal PTH via to interconnect main circuit board 310 and bridge circuit board 320 is avoided, freeing up some amount of space in main circuit board 310. Note that solder dots 330 and 332 may still be provided for purposes of mechanical stability.

Note that a wave solder protection material may be adapted to a connection arrangement during manufacture to avoid wave solder material intrusion to the main-to-bridge circuit board border and prevent re-flow solder fusion. Referring now to FIG. 4, shown is a block diagram of another connection arrangement. In the illustration of FIG. 4, architecture 100″ may be adapted similarly to that of FIGS. 1 and 2 (note that a 2-DIMM architecture is presented in FIG. 4). However, here note the presence of protection members 170 and 175, which may be adapted to the interfaces between main circuit board 110 and bridge circuit board 120 and further located at the interface of an internal via within bridge circuit board 120. In an embodiment, protection members 170 and 175 may be formed of plastic or other non-conductive material. By way of these protection members, solder material intrusion can be prevented. In an embodiment, these members may be adapted to the circuit board arrangement prior to a wave soldering operation (and after a re-flow operation and the joining of bridge circuit board 120 to main circuit board 110). Understand that after wave solder processing is completed, these members may be removed.

By using embodiments as described herein, high-volume PCB manufacturing can be realized in a manner that reduces board costs by way of reduced numbers of internal layers, providing a connector-less T-topology. Furthermore, as the bridge device cost is minimal given its small size, high density interconnect (HDI) technology can be used while realizing low cost production. Understand that the impedance of transmission lines can be tightly controlled within the main circuit board also.

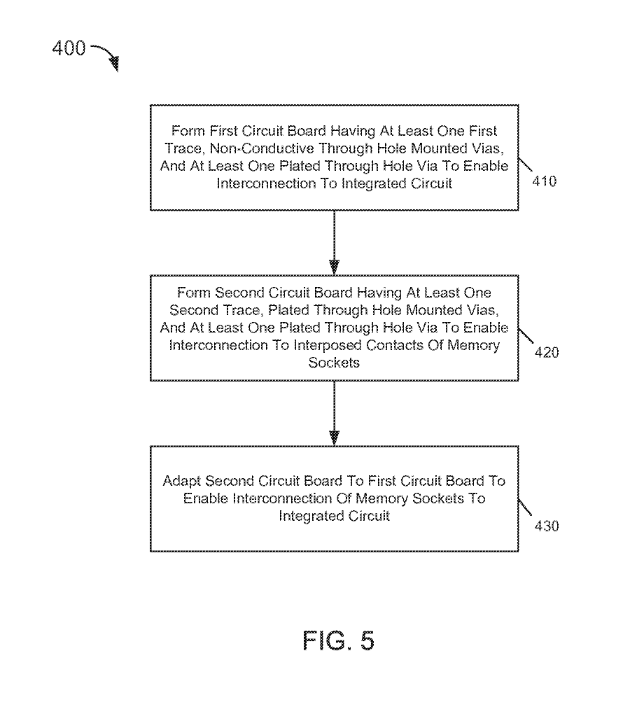

Referring now to FIG. 5, shown is a flow diagram of a method for forming a multi-circuit board arrangement as described herein. As seen, method 400 may be performed during manufacturing operations, e.g., during manufacturing of circuit board arrangements, such as by an original equipment manufacturer (OEM) of various computing device types, or of a supplier to such OEM or other system manufacturer or fabricator. As illustrated, method 400 begins by forming a first circuit board having at least one trace, at least one non-conductive THM via, and at least one plated through hole via (block 410). This forming operation may be performed during PCB manufacturing, in which multiple metal layers may be adapted between different non-conductive layers. Thereafter, the layers may be pressed together to form the multi-layer circuit board. Then various drilling, electroplating and solder operations may be performed to form the plated through holes and any other vias or interconnections as used herein. By way of forming the trace, and vias, electrical interconnection to one or more integrated circuits that are to be adapted to the circuit board can be realized.

Next at block 420 a second circuit board may be formed. This second circuit board may be a bridge circuit board as described herein, and as such may be of a relatively smaller size, fewer layers and complexity as a main circuit board. Similarly the second board may have at least one trace, at least one plated THM via, and one or more plated through vias. By way of these connections, after manufacture, interconnection of interposed contacts of memory sockets (that in turn are adapted to the first circuit board) is realized.

Finally, control passes to block 430 where the two circuit boards can be adapted together. In an embodiment, these circuit boards can be joined at one or more places by a combination of conductive and/or non-conductive solder connections such as bumps, dots or so forth. By adapting the circuit boards together in a manner that electrical interconnection between through hole vias of the two circuit boards make contact, interconnection of the memory sockets to at least one integrated circuit is realized. Further, this arrangement enables a connector-less T-topology without the encumbrances encountered by forming such topology on the main circuit board. Understand while shown with these particular operations and order in FIG. 5, the different circuit boards can be manufactured in any order and of course other operations may be involved in the manufacture.

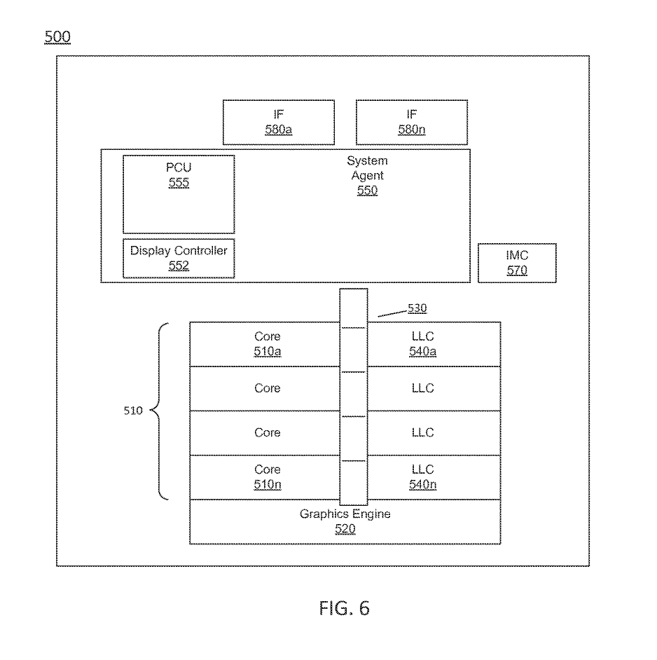

Referring now to FIG. 6, shown is a block diagram of a multi-domain processor in accordance with an embodiment of the present invention. Such processor or SoC may correspond to IC 160 of FIG. 2. As shown in the embodiment of FIG. 6, processor 500 includes multiple domains. Specifically, a core domain 510 can include a plurality of cores 510a-510n, a graphics domain 520 can include one or more graphics engines, and a system agent domain 550 may further be present. In some embodiments, system agent domain 550 may execute at an independent frequency than the core domain and may remain powered on at all times to handle power control events and power management. Each of domains 510 and 520 may operate at different voltage and/or power.

In general, each core 510 may further include low level caches in addition to various execution units and additional processing elements. In turn, the various cores may be coupled to each other and to a shared cache memory formed of a plurality of units of a last level cache (LLC) 540a-540n. In various embodiments, LLC 540 may be shared amongst the cores and the graphics engine, as well as various media processing circuitry. As seen, a ring interconnect 530 thus couples the cores together, and provides interconnection between the cores, graphics domain 520 and system agent circuitry 550. As further seen, system agent domain 550 may include display controller 552 which may provide control of and an interface to an associated display. As further seen, system agent domain 550 may include a power control unit 555 which can include logic to perform power management techniques.

As further seen in FIG. 6, processor 500 can further include an integrated memory controller (IMC) 570 that can provide for an interface to a system memory, such as a dynamic random access memory (DRAM), which may be implemented as DIMMs. In embodiments herein, a connectorless T-topology (via primary and secondary circuit boards) may provide interconnection between multiple DIMM sockets adapted to the primary circuit board and pins or bumps of processor 500 to IMC 570. Multiple interfaces 580a-580n may be present to enable interconnection between the processor and other circuitry. For example, in one embodiment at least one direct media interface (DMI) interface may be provided as well as one or more PCIe™ interfaces. Still further, to provide for communications between other agents such as additional processors or other circuitry, one or more QPI interfaces may also be provided. Although shown at this high level in the embodiment of FIG. 6, understand the scope of the present invention is not limited in this regard.

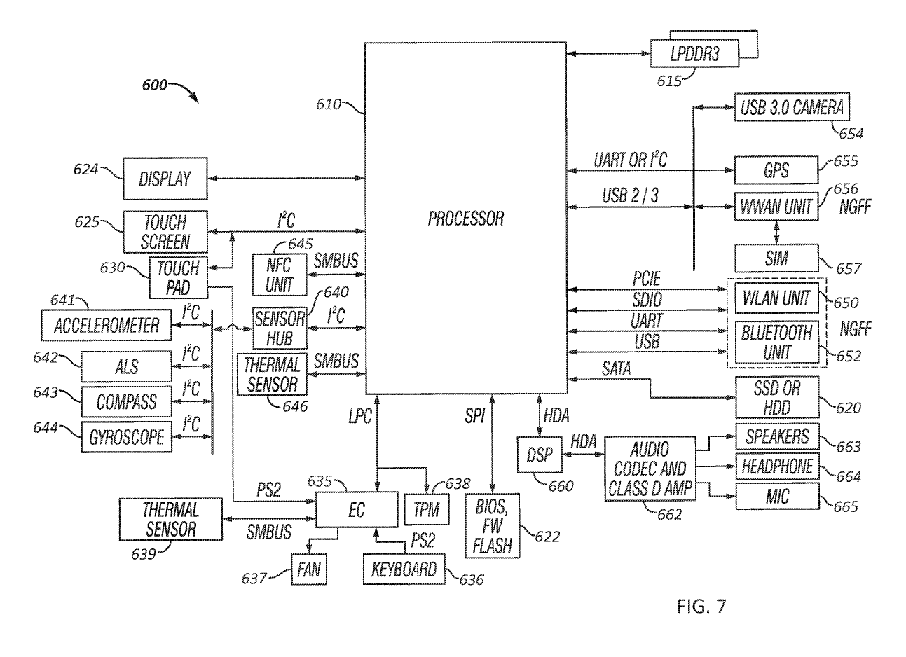

Referring now to FIG. 7, shown is a block diagram of a representative computer system such as notebook, Ultrabook™ or other small form factor system. A processor 610, in one embodiment, includes a microprocessor, multi-core processor, multithreaded processor, an ultra low voltage processor, an embedded processor, or other known processing element. In the illustrated implementation, processor 610 acts as a main processing unit and central hub for communication with many of the various components of the system 600. As one example, processor 610 is implemented as a SoC and may be adapted to a circuit based arrangement as described herein.

Processor 610, in one embodiment, communicates with a system memory 615. As an illustrative example, the system memory 615 is implemented via multiple memory devices or modules which may be connected in a connector-less T-topology, as described herein.

Also shown in FIG. 7, a flash device 622 may be coupled to processor 610, e.g., via a serial peripheral interface (SPI). This flash device may provide for non-volatile storage of system software, including a basic input/output software (BIOS) as well as other firmware of the system.

Various input/output (I/O) devices may be present within system 600. Specifically shown in the embodiment of FIG. 7 is a display 624 which may be a high definition LCD or LED panel that further provides for a touch screen 625. In one embodiment, display 624 may be coupled to processor 610 via a display interconnect that can be implemented as a high performance graphics interconnect. Touch screen 625 may be coupled to processor 610 via another interconnect, which in an embodiment can be an I²C interconnect. As further shown in FIG. 7, in addition to touch screen 625, user input by way of touch can also occur via a touch pad 630 which may be configured within the chassis and may also be coupled to the same I²C interconnect as touch screen 625.

For perceptual computing and other purposes, various sensors may be present within the system and may be coupled to processor 610 in different manners. Certain inertial and environmental sensors may couple to processor 610 through a sensor hub 640, e.g., via an I²C interconnect. In the embodiment shown in FIG. 7, these sensors may include an accelerometer 641, an ambient light sensor (ALS) 642, a compass 643 and a gyroscope 644. Other environmental sensors may include one or more thermal sensors 646 which in some embodiments couple to processor 610 via a system management bus (SMBus) bus.

Also seen in FIG. 7, various peripheral devices may couple to processor 610 via a low pin count (LPC) interconnect. In the embodiment shown, various components can be coupled through an embedded controller 635. Such components can include a keyboard 636 (e.g., coupled via a PS2 interface), a fan 637, and a thermal sensor 639. In some embodiments, touch pad 630 may also couple to EC 635 via a PS2 interface. In addition, a security processor such as a trusted platform module (TPM) 638 may also couple to processor 610 via this LPC interconnect.

System 600 can communicate with external devices in a variety of manners, including wirelessly. In the embodiment shown in FIG. 7, various wireless modules, each of which can correspond to a radio configured for a particular wireless communication protocol, are present. One manner for wireless communication in a short range such as a near field may be via a near field connection (NFC) unit 645 which may communicate, in one embodiment with processor 610 via an SMBus. As further seen in FIG. 7, additional wireless units can include other short range wireless engines including a WLAN unit 650 and a Bluetooth™ unit 652.

In addition, wireless wide area communications, e.g., according to a cellular or other wireless wide area protocol, can occur via a WWAN unit 656 which in turn may couple to a subscriber identity module (SIM) 657. In addition, to enable receipt and use of location information, a GPS module 655 may also be present. Note that in the embodiment shown in FIG. 7, WWAN unit 656 and an integrated capture device such as a camera module 654 may communicate via a given link.

To provide for audio inputs and outputs, an audio processor can be implemented via a digital signal processor (DSP) 660, which may couple to processor 610 via a high definition audio (HDA) link. Similarly, DSP 660 may communicate with an integrated coder/decoder (CODEC) and amplifier 662 that in turn may couple to output speakers 663 which may be implemented within the chassis. Similarly, amplifier and CODEC 662 can be coupled to receive audio inputs from a microphone 665 which in an embodiment can be implemented via dual array microphones (such as a digital microphone array) to provide for high quality audio inputs to enable voice-activated control of various operations within the system. Note also that audio outputs can be provided from amplifier/CODEC 662 to a headphone jack 664. Although shown with these particular components in the embodiment of FIG. 7, understand the scope of the present invention is not limited in this regard.

The following examples pertain to further embodiments.

In one example, an apparatus comprises: a first circuit board including a first trace to electrically couple a first integrated circuit to a first via of the first circuit board; and a second circuit board including a second trace to electrically couple a first contact of a first memory socket adapted to the first circuit board and a first contact of a second memory socket adapted to the first circuit board. The second trace is to electrically couple to a first via of the second circuit board, the first via of the second board to electrically couple to the first via of the first circuit board.

In an example, the first circuit board comprises a first non-conductive via through which the first contact of the first memory socket is adapted.

In an example, the second circuit board comprises a second via into which the first contact of the first memory socket is adapted, where the second via of the second circuit board is to electrically couple the first contact of the first memory socket to the second trace of the second circuit board.

In an example, the first circuit board comprises a second non-conductive via through which the first contact of the second memory socket is adapted, and the second circuit board comprises a third via into which the first contact of the second memory socket is adapted, where the third via of the second circuit board is to electrically couple the first contact of the second memory socket to the second trace of the second circuit board.

In an example, the second circuit board further comprises a fourth via into which a first contact of a third memory socket adapted to the first circuit board is adapted, where the fourth via of the second circuit board is to electrically couple the first contact of the third memory socket to the second trace of the second circuit board.

In an example, the first circuit board comprises a memory interconnection region including the first memory socket and the second memory socket, where the second circuit board is adapted to the first circuit board within the memory interconnection region, the second circuit board having a width substantially co-extensive with the memory interconnection region.

In an example, the first circuit board further comprises at least one circuit region having at least the first integrated circuit, where the second circuit board is not co-extensive with the at least one circuit region.

In an example, a first solder material may be adapted to electrically couple the first via of the first circuit board to the first via of the second circuit board. A second solder material and a third solder material may be adapted between the first circuit board and a periphery of the second circuit board. A fourth solder material is adapted to a second side of the second circuit board to ensure electrical connection between the first contact of the first memory socket and the second via of the second circuit board. In an example, the first, second and third solder material are to be adapted during a re-flow solder process and the fourth solder material is to be adapted during a wave solder process.

In an example, a plurality of non-conductive protective devices may be adapted to the second side of the second circuit board and to an interface region between the first circuit board and the second circuit board. These non-conductive protective devices may be adapted to protect at least the first, second and third solder material from intrusion during the wave solder process.

In an example, the first circuit board and the second circuit board comprise a connector-less T-topology for the plurality of memory sockets.

In another example, an apparatus comprises: a first circuit board and a second circuit board. The first circuit board may include a first trace to electrically couple an integrated circuit to a first conductive via of the first circuit board, the first circuit board having a first memory socket and a second memory socket adapted thereto, the first conductive via to receive and electrically couple to a first contact of the first memory socket. The second circuit board may couple to the first circuit board to enable a T-topology connection between the first memory socket and the second memory socket without interconnection of the first memory socket and the second memory socket on the first circuit board.

In an example, the second circuit board comprises a second trace to electrically couple the first contact of the first memory socket and a first contact of the second memory socket, a first conductive via to receive and electrically couple the first contact of the first memory socket to the second trace, and a second conductive via to receive and electrically couple the first contact of the second memory socket to the second trace.

In an example, the first conductive via of the first circuit board comprises a through hole mounted via to receive and electrically couple to the first contact of the first memory socket, the first circuit board further having a first non-conductive via to receive the first contact of the second memory socket.

In an example, the first contact of the first memory socket comprises a press fit contact, and the first contact of the second memory socket comprises a non-press fit contact.

In an example, the first circuit board further has a third memory socket adapted thereto, and the second circuit board includes a third conductive via to receive and electrically couple a first contact of the third memory socket to the second trace.

In another example, a system comprises: a processor including a plurality of cores and a memory controller; a first memory module including a first plurality of memory devices; a second memory module including a second plurality of memory devices; a main circuit board having a first memory socket to receive the first memory module, the first memory socket having a first contact to extend through the main circuit board, the main circuit board further having a second memory socket to receive the second memory module, the second memory socket having a second contact to extend through the main circuit board, the main circuit board having the processor adapted thereon, where the main circuit board comprises a first trace to electrically couple the processor to a first via of the main circuit board; and a second circuit board coupled to the main circuit board and comprising a second trace to enable electrical interconnection of the first contact of the first memory socket, the second contact of the second memory socket, and the first via of the main circuit board, to electrically couple the first memory module and the second memory module to the processor.

In an example, the second circuit board further comprises a first conductive via to receive and electrically couple the first contact of the first memory socket to the second trace, a second conductive via to receive and electrically couple the second contact of the second memory socket to the second trace, and a third via to electrically couple the second trace to the first via of the main circuit board.

In an example, the second circuit board comprises a bridge circuit board to couple to a second side of the main circuit board, where the first memory socket and the second memory socket are adapted to a first side of the main circuit board opposite to the second side.

Embodiments may be used in many different types of systems. For example, in one embodiment a communication device can be arranged to perform the various methods and techniques described herein. Of course, the scope of the present invention is not limited to a communication device, and instead other embodiments can be directed to other types of apparatus for processing instructions, or one or more machine readable media including instructions that in response to being executed on a computing device, cause the device to carry out one or more of the methods and techniques described herein.

Embodiments may be implemented in code and may be stored on a non-transitory storage medium having stored thereon instructions which can be used to program a system to perform the instructions. Embodiments also may be implemented in data and may be stored on a non-transitory storage medium, which if used by at least one machine, causes the at least one machine to fabricate at least one integrated circuit to perform one or more operations. The storage medium may include, but is not limited to, any type of disk including floppy disks, optical disks, solid state drives (SSDs), compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), magnetic or optical cards, or any other type of media suitable for storing electronic instructions.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An apparatus comprising:
a first circuit board including a first trace to electrically couple a first integrated circuit to a first via of the first circuit board; and
a second circuit board including a second trace to electrically couple a first contact of a first memory socket adapted to the first circuit board and a first contact of a second memory socket adapted to the first circuit board, wherein the second trace is to electrically couple to a first via of the second circuit board, the first via of the second board to electrically couple to the first via of the first circuit board.

2. The apparatus of claim 1, wherein the first circuit board comprises a first non-conductive via through which the first contact of the first memory socket is adapted.

3. The apparatus of claim 2, wherein the second circuit board comprises a second via into which the first contact of the first memory socket is adapted, wherein the second via of the second circuit board is to electrically couple the first contact of the first memory socket to the second trace of the second circuit board.

4. The apparatus of claim 3, wherein the first circuit board comprises a second non-conductive via through which the first contact of the second memory socket is adapted, and wherein the second circuit board comprises a third via into which the first contact of the second memory socket is adapted, wherein the third via of the second circuit board is to electrically couple the first contact of the second memory socket to the second trace of the second circuit board.

5. The apparatus of claim 4, wherein the second circuit board further comprises a fourth via into which a first contact of a third memory socket adapted to the first circuit board is adapted, wherein the fourth via of the second circuit board is to electrically couple the first contact of the third memory socket to the second trace of the second circuit board.

6. The apparatus of claim 1, wherein the first circuit board comprises a memory interconnection region including the first memory socket and the second memory socket, wherein the second circuit board is adapted to the first circuit board within the memory interconnection region, the second circuit board having a width substantially co-extensive with the memory interconnection region.

7. The apparatus of claim 6, wherein the first circuit board further comprises at least one circuit region having at least the first integrated circuit, wherein the second circuit board is not co-extensive with the at least one circuit region.

8. The apparatus of claim 1, further comprising a first solder material to electrically couple the first via of the first circuit board to the first via of the second circuit board.

9. The apparatus of claim 8, further comprising a second solder material and a third solder material adapted between the first circuit board and a periphery of the second circuit board.

10. The apparatus of claim 9, further comprising a fourth solder material adapted to a second side of the second circuit board to ensure electrical connection between the first contact of the first memory socket and the second via of the second circuit board.

11. The apparatus of claim 10, wherein the first, second and third solder material are to be adapted during a re-flow solder process and the fourth solder material is to be adapted during a wave solder process.

12. The apparatus of claim 11, further comprising a plurality of non-conductive protective devices to be adapted to the second side of the second circuit board and to an interface region between the first circuit board and the second circuit board, the plurality of non-conductive protective devices to protect at least the first, second and third solder material from intrusion during the wave solder process.

13. The apparatus of claim 1, wherein the first circuit board and the second circuit board comprise a connector-less T-topology for the plurality of memory sockets.

14. An apparatus comprising:
a first circuit board including a first trace to electrically couple an integrated circuit to a first conductive via of the first circuit board, the first circuit board having a first memory socket and a second memory socket adapted thereto, the first conductive via to receive and electrically couple to a first contact of the first memory socket; and
a second circuit board to couple to the first circuit board to enable a T-topology connection between the first memory socket and the second memory socket without interconnection of the first memory socket and the second memory socket on the first circuit board.

15. The apparatus of claim 14, wherein the second circuit board comprises a second trace to electrically couple the first contact of the first memory socket and a first contact of the second memory socket, a first conductive via to receive and electrically couple the first contact of the first memory socket to the second trace, and a second conductive via to receive and electrically couple the first contact of the second memory socket to the second trace.

16. The apparatus of claim 14, wherein the first conductive via of the first circuit board comprises a through hole mounted via to receive and electrically couple to the first contact of the first memory socket, the first circuit board further having a first non-conductive via to receive the first contact of the second memory socket.

17. The apparatus of claim 16, wherein the first contact of the first memory socket comprises a press fit contact, and the first contact of the second memory socket comprises a non-press fit contact.

18. The apparatus of claim 15, the first circuit board further having a third memory socket adapted thereto, and the second circuit board including a third conductive via to receive and electrically couple a first contact of the third memory socket to the second trace.

19. A system comprising:
a processor including a plurality of cores and a memory controller;
a first memory module including a first plurality of memory devices;
a second memory module including a second plurality of memory devices;
a main circuit board having a first memory socket to receive the first memory module, the first memory socket having a first contact to extend through the main circuit board, the main circuit board further having a second memory socket to receive the second memory module, the second memory socket having a second contact to extend through the main circuit board, the main circuit board having the processor adapted thereon, wherein the main circuit board comprises a first trace to electrically couple the processor to a first via of the main circuit board; and
a second circuit board coupled to the main circuit board and comprising a second trace to enable electrical interconnection of the first contact of the first memory socket, the second contact of the second memory socket, and the first via of the main circuit board, to electrically couple the first memory module and the second memory module to the processor.

20. The system of claim 19, wherein the second circuit board further comprises a first conductive via to receive and electrically couple the first contact of the first memory socket to the second trace, a second conductive via to receive and electrically couple the second contact of the second memory socket to the second trace, and a third via to electrically couple the second trace to the first via of the main circuit board.

21. The system of claim 19, wherein the second circuit board comprises a bridge circuit board to couple to a second side of the main circuit board, wherein the first memory socket and the second memory socket are adapted to a first side of the main circuit board opposite to the second side.
